(19) United States
(12) Patent Application Publication
(10) Pub. No.: US 2009/0293809 A1
(43) Pub. Date: Dec. 3, 2009

(54) STAGE UNIT FOR SUPPORTING A SUBSTRATE AND APPARATUS FOR PROCESSING A SUBSTRATE INCLUDING THE SAME

(76) Inventors: Sang-Bum Cho, Seoul (KR); Byung-Jin Jung, Seoul (KR); Myoung-Ha Park, Anseong-si (KR)

Correspondence Address: DALY, CROWLEY, MOFFORD & DURKEE, LLP, SUITE 301A, 354A TURNPIKE STREET, CANTON, MA, 02021-2714, US

(21) Appl. No.: 12/473,316

(22) Filed: May 28, 2009

(30) Foreign Application Priority Data
May 28, 2008 (KR) 10-2008-0049708

(51) Int. Cl. H01L 21/683; C23C 16/00

(52) U.S. Cl. 118/725; 219/444.1; 219/458.1

(57) ABSTRACT

In a stage for supporting a substrate, a body, a base plate and a buffer are provided in the stage. The body on which the substrate is positioned includes a plate having a heating electrode for generating heat therein and a tube protruded from a bottom surface of the plate. The body is mounted on the base plate. The buffer is interposed between the base plate and the tube and has a thermal expansion ratio higher than that of the tube of the body and lower than that of the base plate. Accordingly, thermal expansion of the base plate may be absorbed by the buffer and may not have direct effect on the body. Therefore, the body may be prevented from being damaged due to the thermal expansion of the base plate.

### CROSS REFERENCE TO RELATED APPLICATION

This application claims priority under 35 USC § 119 to Korean Patent Application No. 2008-49708, filed on May 28, 2008 in the Korean Intellectual Property Office (KIPO), the contents of which are herein incorporated by reference in their entirety.

### BACKGROUND

1. Field

Example embodiments relate to a stage unit for supporting a substrate and an apparatus for processing a substrate including the same, and more particularly, to a stage unit for supporting a substrate on which integrated circuit devices are manufactured and an apparatus for processing the substrate including the same.

2. Description of the Related Art

Generally, integrated circuit devices are manufactured through a series of unit processes, for example, a deposition process, an etching process, a photolithography process, an ion implantation process, etc., that is performed on a substrate such as a semiconductor substrate or a glass substrate.

The above unit processes are usually performed in an apparatus for processing the substrate (hereinafter referred to as processing apparatus) including a process chamber in which a space for performing the unit process is provided and a stage unit on which the substrate is positioned in the processing apparatus. That is, the substrate is loaded into the space of the process chamber from the exterior of the processing apparatus and is positioned and fixed on the stage unit that is installed in the process chamber.

When various unit processes are performed on the same processing apparatus, the process chamber of the processing apparatus undergoes various processing environments and conditions. For example, when the deposition process and the etching process are performed on the same processing apparatus, various source gases such as deposition gases and etching gases are supplied into the same process chamber. In addition, a conventional deposition process and an etching process require a low internal pressure, almost a vacuum state, and an extremely high internal temperature in the process chamber of the processing apparatus. Particularly, when the deposition and etching processes are performed using plasma, the high internal temperature requirement of the process chamber is a prerequisite to the deposition and etching processes in the process apparatus.

The stage unit in the process chamber usually includes a base secured to the bottom of the process chamber and a body making contact with the base. The substrate is positioned on the body of the stage unit.

The body of the stage unit includes a plate having built-in electrodes and a tube protruded from a bottom surface of the plate and having a plurality of wirings electrically connected to the electrode. The substrate is usually positioned on the plate.

Each of the wirings is enclosed by an insulation layer and is compactly arranged in the tube adjacent to each other. When the stage unit undergoes linear and rotational motion in the processing apparatus, the insulation layer of the neighboring wirings may be easily worn off at the joint portion of the tube and the plate, and thus the neighboring wirings may short circuit.

In addition, the base usually includes a metal having good rigidity, and thus there is little possibility of the base being damaged. However, the body usually includes a ceramic-based material so as to prevent damage caused by plasma, and thus there is high possibility of the body being damaged due to the difference of the thermal expansion ratio between the base and the body under the high temperature conditions of the process chamber.

### SUMMARY

Example embodiments provide a stage for a processing apparatus in which an electrical short circuit of the neighboring wirings and damage to the body due to thermal expansion of the base may be minimized.

Example embodiments provide a processing apparatus having the above stage.

According to some example embodiments of the present inventive concept, there is provided a stage for a processing apparatus including a body and a first insulation section. The body on which the substrate may be positioned includes a plate having an electrode member therein and a tube protruded from a bottom surface of the plate and through which wirings are extended from the electrode member. The first insulation section may be inserted into the tube and having a plurality of first holes through which the wirings are inserted, respectively.

In an example embodiment, the stage unit may further include a filling member interposed between an inner wall of the tube and the first insulation section, so that a gap distance between the tube and the first insulation section is uniform along the inner wall of the tube. The filling member further includes a protrusion making contact with the first insulation section.

In an example embodiment, the electrode member in the plate includes a heating electrode for generating heat and the base includes a base plate on which the body is mounted and a buffer interposed between the base plate and the tube of the body, the buffer having a thermal expansion ratio higher than that of the tube of the body and lower than that of the base plate.

In an example embodiment, the buffer includes a first through-hole connected to the tube and the base plate includes a second through-hole connected to the first through-hole and the tube. The first insulation section may penetrate though the first and second through-holes, so that the first insulation section is extended to the exterior of the stage. Otherwise, the stage may further include a second insulation section combined to the first insulation section through the first and second through-holes, the second insulation section including a plurality of second holes through which the wirings are individually inserted.

In an example embodiment, the stage may further include a protection block interposed between the plate and the base plate and enclosing the tube of the body, so that the base plate is covered with the protection block and is protected from processing gases for processing the substrate.

The protection block may be spaced apart from the plate having the heating electrode, to thereby prevent heat transfer from the plate to the protection block. A gap distance between the protection block and the plate may be in a range of about 0.05 mm to about 7 mm.

The protection block may be separated into at least two portions.

In an example embodiment, the stage may further include a first sealing unit interposed between the tube and the buffer and a second sealing unit interposed between the base plate and the buffer, so that the interior of the tube is sealed off from the exterior of the tube by the first and second sealing units.

In an example embodiment, the stage may further include a first joint member for combining the tube and the buffer and a second joint member for combining the buffer and the base plate.

According to some example embodiments of the present inventive concept, there is provided another stage for supporting a substrate including a body, a base plate and a buffer. The body on which the substrate is positioned may include a plate having a heating electrode for generating heat therein and a tube protruded from a bottom surface of the plate. The body is mounted on the base plate and the buffer may be interposed between the base plate and the tube. The buffer may have a thermal expansion ratio higher than that of the tube of the body and lower than that of the base plate.

In an example embodiment, the stage may further include a protection block interposed between the plate and the base plate and enclosing the tube of the body, so that the base plate is covered with the protection block and is protected from processing gases for processing the substrate.

According to some example embodiments of the present inventive concept, there is provided an apparatus for processing a substrate. The apparatus may include a process chamber, a gas supplier and a stage on which the substrate is positioned. The process chamber may include a space in which the substrate is processed and the gas supplier may be connected to the process chamber and process gases for processing the substrate may be supplied into the process chamber through the gas supplier. The stage may be positioned in the process chamber and support the substrate. The stage may include a body on which the substrate is positioned and a first insulation section. The body may include a plate having an electrode member therein and a tube protruded from a bottom surface of the plate and through which wirings are extended from the electrode member and the first insulation section may be inserted into the tube and have a plurality of first holes through which the wirings are inserted, respectively.

In an example embodiment, the electrode member in the plate may include a heating electrode for generating heat and the base may include a base plate on which the body is mounted and a buffer interposed between the base plate and the tube of the body. The buffer may have a thermal expansion ratio higher than that of the tube of the body and lower than that of the base plate.

In an example embodiment, the stage may further include a protection block interposed between the plate and the base plate and enclosing the tube of the body, so that the base plate may be covered with the protection block and may be protected from processing gases for processing the substrate.

According to some example embodiments of the present inventive concept, wirings in a tube of a body of a stage are inserted into holes of an insulation section, respectively, and thus movement and electrical short circuits of the wirings may be sufficiently prevented.

In addition, thermal expansion of a base plate may be absorbed by a buffer and may not have direct effect on the body. Therefore, the body may be prevented from being damaged due to the thermal expansion of the base plate.

Accordingly, failures of the stage may be sufficiently minimized, to thereby improve the efficiency of a process performed in a process chamber using the stage.

### BRIEF DESCRIPTION OF THE DRAWINGS

Example embodiments will be more clearly understood from the following detailed description taken in conjunction with the accompanying drawings. FIGS. 1 to 3 represent non-limiting, example embodiments as described herein.

FIG. 1 is a cross-sectional view illustrating a stage unit for a processing apparatus in accordance with an example embodiment of the present invention;

FIG. 2 is a disassembled view of the stage unit shown in FIG. 1;

FIG. 3 is a cross-sectional view taken along a line I-I′ of FIG. 1;

FIG. 4 is a partially enlarged cross-sectional view of a portion A in FIG. 1; and

FIG. 5 is a cross-sectional view illustrating a schematic structure of an apparatus for processing a substrate in accordance with an example embodiment of the present invention.

### DETAILED DESCRIPTION OF THE EMBODIMENTS

Various example embodiments will be described more fully hereinafter with reference to the accompanying drawings, in which some example embodiments are shown. The present invention may, however, be embodied in many different forms and should not be construed as limited to the example embodiments set forth herein. Rather, these example embodiments are provided so that this disclosure will be thorough and complete, and will fully convey the scope of the present invention to those skilled in the art. In the drawings, the sizes and relative sizes of layers and regions may be exaggerated for clarity.

It will be understood that when an element or layer is referred to as being “on,” “connected to” or “coupled to” another element or layer, it can be directly on, connected or coupled to the other element or layer or intervening elements or layers may be present. In contrast, when an element is referred to as being “directly on,” “directly connected to” or “directly coupled to” another element or layer, there are no intervening elements or layers present. Like numerals refer to like elements throughout. As used herein, the term “and/or” includes any and all combinations of one or more of the associated listed items.

It will be understood that, although the terms first, second, third, etc. may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings of the present invention.

Spatially relative terms, such as “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly.

The terminology used herein is for the purpose of describing particular example embodiments only and is not intended to be limiting of the present invention. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Example embodiments are described herein with reference to cross-sectional illustrations that are schematic illustrations of idealized example embodiments (and intermediate structures). As such, variations from the shapes of the illustrations as a result, for example, of manufacturing techniques and/or tolerances, are to be expected. Thus, example embodiments should not be construed as limited to the particular shapes of regions illustrated herein but are to include deviations in shapes that result, for example, from manufacturing. For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the figures are schematic in nature and their shapes are not intended to illustrate the actual shape of a region of a device and are not intended to limit the scope of the present invention.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

Hereinafter; example embodiments will be explained in detail with reference to the accompanying drawings.

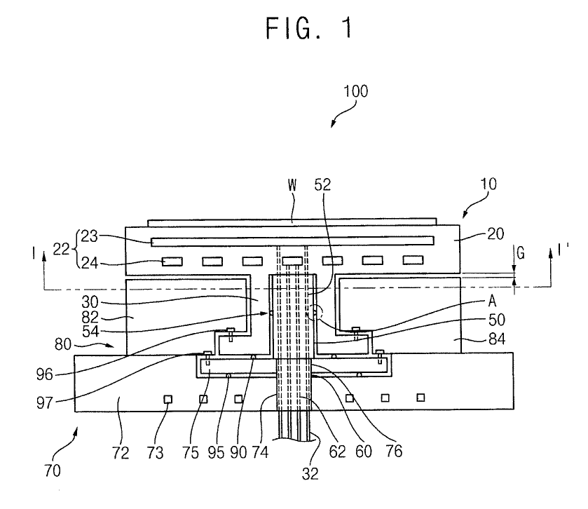

FIG. 1 is a cross-sectional view illustrating a stage unit for a processing apparatus in accordance with an example embodiment of the present invention.

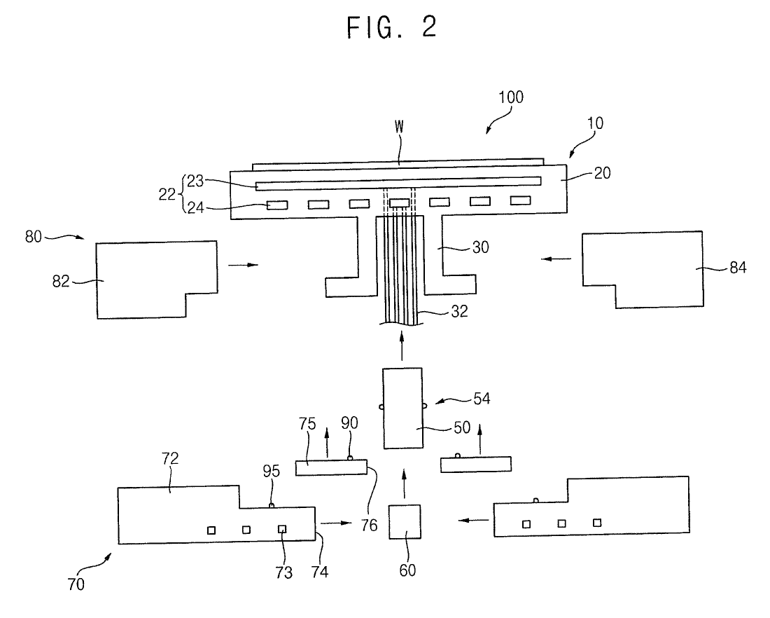

FIG. 2 is a disassembled view of the stage unit shown in FIG. 1.

Referring to FIGS. 1 and 2, a stage unit 100 for a processing apparatus in accordance with an example embodiment of the present invention may include a body 10, a first insulation section 50 and a base 70.

In an example embodiment, the body 10 may include a plate 20 and a tube 30. A substrate w may be positioned on the plate 20. For example, the substrate w may include a silicon wafer for manufacturing a semiconductor device and a flat glass substrate on which a thin-film transistor (TFT) or a color filter for a flat panel display device is formed.

An electrode member 22 may be installed in the interior of the plate 20. In the present example embodiment, the electrode member 22 may include a first electrode generating an electrostatic force and a second electrode generating heat. A driving voltage may be applied to the first electrode 23 and the electrostatic force may be generated from the first electrode, and thus the substrate w may be secured onto the plate 20 by the electrostatic force. The first electrode 23 may include a material having a low electrical resistance and a low thermal expansion ratio such as tungsten (W), molybdenum (Mo), silver (Ag) and gold (Au). In the present example embodiment, the first electrode 23 may have a thickness of about 10 μm to about 200 μm.

A driving voltage may be applied to the second electrode 24 and the heat is generated from the second electrode, to thereby heat the substrate W. Thus, the process on the substrate W, such as a deposition process or an etching process, may be facilitated in the process apparatus. The second electrode 24 may include substantially the same material as the first electrode and may have a thickness of about 50 μm to about 300 μm.

In the present example embodiment, the first electrode 23 may be positioned above the second electrode 24, thus the substrate W may be easily secured to the plate 20.

The electrode member 22 may further include a ground electrode (not shown) for applying a high frequency voltage, and thus plasma may be generated in a space of a process chamber when the deposition or the etching process may be performed in the processing apparatus. Particularly, the first electrode 23 may be used as the ground electrode, as would be known to one of ordinary skill in the art.

In an example embodiment, the plate 20 may include a ceramic-based material having a good mechanical rigidity, and thus the electrode member 22 in the plate 20 may be electrically protected from surroundings. Examples of the ceramic-based material may include aluminum nitride (AlN), aluminum oxide (Al2O3), yttrium oxide (Y2O3), silicon carbide (SiC), etc. These may be used alone or in combinations thereof.

In an example embodiment, the tube 30 may be protruded from a bottom surface of the plate 20. For example, a hollow tube may be protruded from a central portion of the bottom surface of the plate 20. The tube 30 may include the same material as the plate 20 and may be integrally formed with the plate 20 in a body. Otherwise, the tube 30 and the plate 20 may be combined with each other after separately manufacturing the tube 30 and the plate 20.

At least two wirings 32 may be positioned in the tube 30 and thus driving power may be applied to the electrode member 22 through the wirings 32. For example, when the first electrode 23 of the electrode member 22 is a monopolar type, three wirings may be provided in the tube 30. However, the number of the wirings 32 may be varied in accordance with the number and the shape of the electrode members 22, as would be known to one of ordinary skill in the art.

The first insulation section 50 may be inserted into the tube 30, and thus the wirings may be insulated from each other and tightly secured to each other by the first insulation section 50. Therefore, the first insulation section 50 may include a material having insulation characteristics and high heat resistance.

For example, the first insulation section 50 may include a ceramic-based material and a high temperature resin having low heat conductivity and a low thermal expansion ratio. Example of the ceramic-based material may include aluminum oxide (Al2O3), yttrium oxide (Y2O3), quartz, etc. These may be used alone or in combinations thereof.

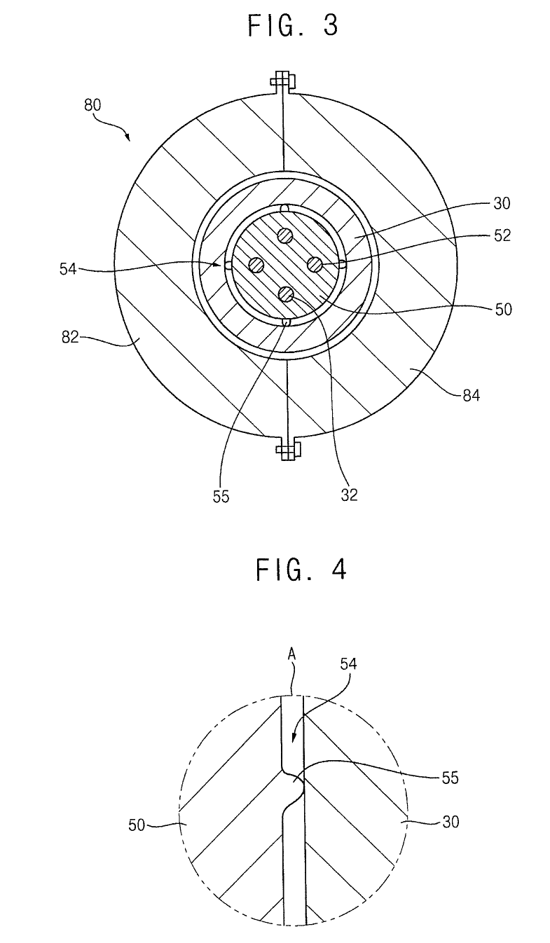

Hereinafter, the first insulation section 50 will be described in detail with reference to FIGS. 3 and 4.

FIG. 3 is a cross-sectional view taken along a line I-I′ of FIG. 1 and FIG. 4 is a partially enlarged cross-sectional view of a portion A in FIG. 1.

Referring additionally to FIGS. 3 and 4, the first insulation section 50 may include a plurality of first holes 52 into which the wirings are inserted, respectively.

Particularly, the first insulation section 50 may be inserted into the tube 30 and closely adhered to the plate 20 in the tube 30 and the wirings 32 in the tube 30 are inserted into the first holes 52 of the first insulation section 50, respectively. Thus, the wirings 32 are electrically insulated from each other and tightly secured into the tube 30 by the first insulation section 50.

In an example embodiment, the first insulation section 50 may be spaced apart from an inner wall of the tube 30 by a gap distance to thereby facilitate the insertion and separation between the first insulation section 50 and the tube 30. Particularly, the first insulation section 50 may have an outer diameter smaller than an inner diameter of the tube 30.

A filling member 54 may be interposed between the first insulation section 50 and the inner wall of the tube 30, and thus the first insulation section 50 may be prevented from moving and the gap distance between the first insulation section 50 and the tube 30 may become uniform.

A plurality of protrusions 55 may be located on a surface of the filling member 54 and the protrusion 55 may make contact with an outer surface of the first insulation section 50, to thereby secure the first insulation section 50 into the tube 30 and to prevent movement of the first insulation section 50 in the tube 30. In the present example embodiment, the protrusions may be arranged on the outer surface of the first insulation section 50 along a circumferential line.

The contact area between the first insulation section 50 and the tube 30 may be minimized due to the filling member 54. Accordingly, even though heat is transferred to the tube 30 from the second electrode 24 in the plate 20, heat transfer to the first insulation section 50 may also be minimized due to the filling member 54. As a result, the heat generated from the second electrode 24 may be much more intensively transferred to an upper portion of the plate 20 and thus the substrate W on the plate 20 may be much more uniformly heated by the second electrode 24.

A surface treatment may be performed on a surface of the filling member 54 to thereby minimize friction with the inner wall of the tube 30. In addition, an end portion of the filling member 54 may be round to thereby become the contact area between the tube 30 and the filling member 54.

The filling member 54 may be integrally formed with one of the first insulation section 50 and the tube in a body. Particularly, the filling member 54 may be formed on the outer surface of the first insulation section 50 or on the inner wall of the tube 30.

The wirings 32 in the tube 30 may be inserted into the first holes 52, respectively, of the first insulation section 50 that is uniformly spaced apart from the tube 30 by the filling member 54. Thus, the first insulation section 50 may be prevented from moving in the tube 30 due to the filling member 54 and may be stably positioned in the tube 30 without any movement. As a result, the wirings 32 may also be stably positioned in the first insulation section 50 in the tube 30 without any movement, to thereby prevent electrical short circuits of the wirings 32 caused by relative movement of the tube 30 and the plate 20.

Therefore, electrical failures of the electrode member 22 may be sufficiently reduced by the stability of the wirings 32 and the heat from the second electrode 24 may be efficiently transferred to the substrate W on the plate 20, to thereby sufficiently improve the processing efficiency of the stage 100.

The base 70 may be positioned below the body 10 and support the body 10 to thereby form the stage 100. For example, the base 70 may be positioned on the bottom of a process chamber (not shown) and the body 10 may be positioned on the base 70.

In an example embodiment, the base 70 may include a base plate 72 functioning as a body and a buffer 75 interposed between the base plate 72 and the tube 30 of the body 10.

For example, the base plate 72 may include a metal having good thermal conductivity, and thus the heat generated from the second electrode 24 in the plate 20 may be radiated outwards through the tube 30. Therefore, the base plate 72 may include aluminum (Al), nickel (Ni), stainless steel, etc.

At least one cooling member 73 may be installed in the interior of the base plate 72 and thus the heat transferred to the base plate 72 may be efficiently removed from the base plate 72, and thus a stable temperature difference may be maintained between the tube 30 and the base plate 72. In the present example embodiment, the cooling member 73 may include pipe through which cold water may flow.

The thermal expansion ratio of the base plate 72 may be higher than that of the body 10 comprising a ceramic-based material due to the high thermal conductivity.

Thus, the buffer 75 may absorb thermal expansion of the base plate 72 between the base plate 72 and the tube 30 of the body 10. The thermal expansion ratio of the buffer 75 may be lower than that of the base plate 72 and higher than that of the tube 30 of the body 10.

For example, the buffer 75 may include a metal such as Kovar (trademark of a nickel-cobalt ferrous alloy manufactured by Carpenter Technology Corporation in the U.S.A.), Invar (FeNi36, trademark of a nickel-steel alloy manufactured by Imphy Alloys Inc. in the U.S.A.), tungsten (W) and molybdenum (Mo) or a nomnetal such as silicon carbide (SiC).

Accordingly, the buffer 75 interposed between the base plate 72 and the tube 30 of the body 10 may have thermal conductivity lower than that of the base plate 72, and thus the thermal expansion of the base plate 72 may be limited by the buffer 75. Therefore, damage to the body 10 caused by the thermal expansion of the base plate 72 may be sufficiently prevented by the buffer 75.

In the present embodiment, when a process is performed with respect to the substrate W on the plate 20 of the body 10 at a temperature no higher than about 400° C., damage to the body 10 caused by thermal expansion of the base plate 72 may be semipermanently prevented.

Therefore, electrical short circuits of the wirings 32 and damage to the body 10 may be sufficiently minimized to thereby reduce damage to the stage 100 and improve the efficiency of the process performed on the substrate W on the stage 100.

A first through-hole 76 may be formed through the buffer 75 and a second through-hole 74 may be formed through the base plate 72. The inside of the tube 30 may be exposed through the first and second through-holes 76 and 74, and thus the wirings 32 in the tube 30 may be extended out of the tube 30 through the first and second through-holes 76 and 74.

The first insulation section 50 may also be extended out of the tube 30 through the first and second through-holes 76 and 74 integrally with the wirings 32 in a body.

Otherwise, the first insulation section 50 may be positioned only in the tube 30 so to thereby facilitate the assembly of the first insulation section 50 with the tube 30, and a second insulation section 60 may be further provided in the first and second through-holes 76 and 74. The second insulation section 60 may be inserted into the first and second through-holes 76 and 74 and be connected to the first insulation section 50.

The first and second insulation sections 50 and 60 may be connected to each other as follows. The first insulation section 50 may be inserted into the tube 30 of the body 10 and then the base 70 including the base plate 72 and the buffer 75 may be assembled to the tube 30 of the body 10. Thereafter, the second insulation section 60 may be inserted into the first and second through-holes 76 and 74 and be connected to the first insulation section 50.

Accordingly, the stage 100 may include the first and second insulation sections 50 and 60 for electrically insulating the wirings 32, and thus the base 70 and the tube 30 may be assembled to each other irrespective of the wirings 32.

In an example embodiment, the stage 100 may further include a protection block 80 enclosing the tube 30 and mounted on the base 70. The protection block 80 may face the bottom surface of the plate 20 and cover the base plate 72 of the plate 70. Therefore, the base plate 72, which includes a metal, of the plate 70 may be prevented from being damaged by a processing gas in performing a process on the substrate W.

A gap G may be provided between the protection block 80 and the plate 20, and thus the heat generated from the second electrode 24 in the plate 20 may be prevented from being transferred to the protection block 80.

Therefore, the heat generated from the second electrode 24 may be transferred to the upper portion of the plate 20 rather than to a lower portion of the plate 20, and thus the substrate W on the plate 20 may be uniformly heated. Particularly, the deposition onto the substrate W and the etching against a thin layer on the substrate W may be much more uniformly performed on the stage 100 due to the gap G between the protection block 80 and the plate 20 of the body 10, to thereby improve the process quality of the deposition and the etching processes.

For example, the gap G may be characterized as a minimal gap distance between the plate 20 and the prevention block 80 for preventing plasma generation from processing gases in a processing chamber for the deposition and the etching processes.

When the gap distance between the plate 20 and the protection block 50 is less than about 0.05 mm, the plate 20 may be so close to the protection block 80 that the heat generated from the second electrode 24 may be transferred to the protection block 80. In contrast, when the gap distance between the plate 20 and the protection block 50 is more than about 7 mm, the processing gases in the process chamber may be easily transformed into plasma. For those reasons, the gap distance between the plate 20 and the protection block 80 may range from about 0.05 mm to about 7 mm, and more particularly, from about 0.1 mm to about 5 mm. That is, the gap G may range from about 0.05 mm to about 7 mm.

In the present example embodiment, the protection block 80 may include a first block 82 and a second block 84 that are symmetrical to each other with respect to the tube 30. Particularly, the first and second blocks 82 and 84 may be positioned around the tube 30 in such a configuration that the tube 30 are surrounded by the first and second blocks 82 and 84. The first and second blocks 82 and 84 may be mounted on the base 70 downward by the load thereof.

In addition, the separation of the protection block 80 into the first and second blocks 82 and 84 may facilitate the maintenance of the stage 100. As a modification of the present example embodiment, a protrusion and a groove corresponding to the protrusion may be interposed between the first and second blocks 82 and 84 and the base 70, and thus relative movement between the protection block 80 and the base 70 may be sufficiently prevented. When the size of the protection block 80 becomes large according to processing conditions and requirements, the protection block 80 would be separated into many portions, as would be known to one of ordinary skill in the art.

In an example embodiment, first and second sealing units 90 and 95 may be positioned around the first and second through-holes 76 and 74, to thereby maintain a vacuum stage in the process chamber including the stage 100 when the deposition process or the etching process may be performed in the process chamber.

The first sealing unit 90 may be interposed between an end portion of the tube 30 and the buffer 75 and the second sealing unit 95 may be interposed between the base plate 72 and the buffer 75.

The first and the second sealing units 90 and 95 may include high heat-resistant and high corrosion-resistant materials such as silicon (Si), Viton (trademark of synthetic rubber and fluoropolymer elastomer manufactured by DuPont in the U.S.A.) and fluorine (F). Therefore, the first and second sealing units 90 and 95 may be sufficiently resistant to plasma process conditions of the process chamber including the stage 100 at a high temperature. However, the first and second sealing unit 90 and 95 may also include a conventional synthetic rubber in accordance with processing conditions in the process chamber including the stage 100, as would be known to one of ordinary skill in the art.

Particularly, the first and second sealing units 90 and 95 may be cooled down by the cooling member 73 in the base plate 72, and thus thermal deterioration of the sealing units 90 and 95 may be prevented by the cooling member 73 despite the high temperature conditions of the process chamber including the stage 100.

In an example embodiment, first and second joint members 96 and 97 may be further provided to the stage 100, and thus the tube 30 and the buffer 75 are secured to each other by the first joint member 96 and the buffer 75 and the base plate 72 may be secured to each other by the second joint member 97. A bolt may be used as the first and the second joint members 96 and 97.

The buffer 75 may be thermally expanded between the tube 30 and the base plate 72, and thus the buffer 75 may need to be secured to the tube 30 and the base plate 72 by the joint members 96 and 97 in place of adhesives.

When the buffer 75 is secured to the tube 30 and the base plate 72 by the adhesives, foreign matter caused by the adhesives may be generated from the stage 100 due to relative movement of the buffer, the tube 30 and the base plate 72. Accordingly, the combination of the buffer 75 with the tube 30 and/or the base plate 72 using the joint members 96 and 97 in place of the adhesives may sufficiently prevent contamination caused by the foreign matters in the stage 100.

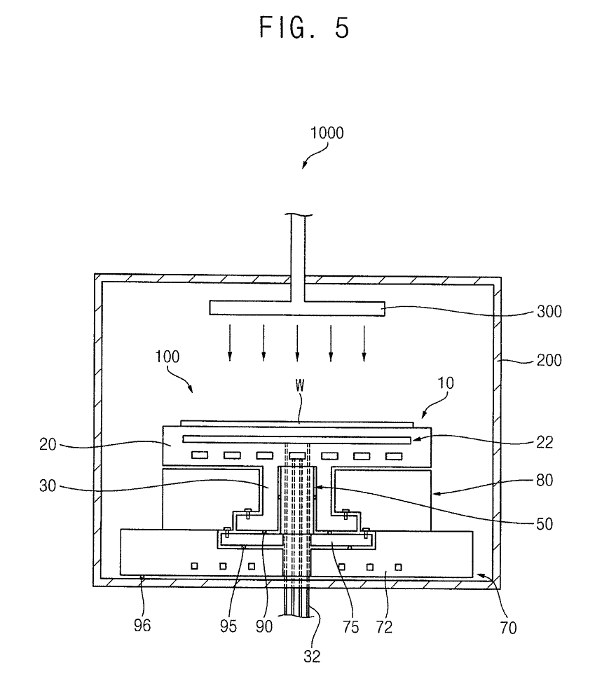

FIG. 5 is a cross-sectional view illustrating a schematic structure of an apparatus for processing a substrate in accordance with an example embodiment of the present invention.

In FIG. 5, the stage 100 in the processing apparatus 1000 may have substantially the same structure as the stage 100 described with reference to FIGS. 1 to 4. Therefore, in FIG. 5, the same reference numerals denote the same elements in FIGS. 1 to 4 and the detailed descriptions of the same elements will be omitted.

Referring to FIG. 5, the processing apparatus 1000 in accordance with an example embodiment of the present invention may include a process chamber 200, a gas supplier 300 and the stage 100.

In an example embodiment, the process chamber 200 may provide an internal space in which a thin layer may be formed on a substrate W by a deposition process and a thin layer on the substrate W may be removed by an etching process. The internal pressure of the process chamber 200 may be maintained at a low pressure such as a vacuum state, to thereby improve the efficiency of the deposition process or the etching process.

In an example embodiment, the gas supplier 300 may be connected to the process chamber 200. Process gases for processing the substrate W may be supplied into the process chamber 200 from an external reservoir (not shown) by the gas supplier 300. The gas supplier 300 may be positioned at an upper portion of the process chamber 200.

For example, the process gases may include source gases for the deposition process, inactive gases for generating plasma from the source gases and etching gases for the etching process. Particularly, when the gas supplier 300 is positioned at the upper portion of the process chamber 200, high-frequency electric power may be applied to the gas supplier 300 for generating the plasma.

The stage 100 may be positioned in the interior of the process chamber 200. For example, when the gas supplier 300 is positioned at the upper portion of the process chamber 200, the stage 100 may be positioned at a lower portion of the process chamber 200 to thereby face the gas supplier 300. The substrate W may be positioned on the stage 100 and the process gas may move downward in the process chamber 200 in performing the deposition process or the etching process.

In an example embodiment, the stage 100 may include the body 10 having the plate 20 and the tube 30, the insulation section 50 and the base 70. The body plate 20 may include the electrode member 22 and the substrate W may be positioned on the plate 20 and the tube 30 may be protruded from the bottom surface of the plate 20. The wirings electrically connected to the electrode member 22 may be extended through the tube 30. The insulation section 50 may be inserted into the tube 30 and electrically insulates neighboring wirings in the tube 30. The base 70 may be positioned on the bottom of the process chamber 200 and the body 10 may be mounted on the base 70.

For example, the wirings 32 may be extended out of the process chamber 200 through the base 70. Otherwise, the wirings 32 may be extended only to the bottom of the process chamber 200 and an additional connector (not shown) may be provided to the process chamber 200 so as to electrically connect the wirings 32 to an external power source (not shown). For example, the additional connector may include a connecting plug that may be inserted into the bottom of the process chamber 200.

The base 70 may be mounted on the bottom of the process chamber 200 and may include a base plate 72 having a first thermal expansion ratio higher than that of the body 10 and a buffer 75 interposed between the base plate 72 and the tube 30 of the body 10 and having a second thermal expansion ratio lower than the first thermal expansion ratio of the base plate 72. That is, the buffer 75 may be less expanded by heat than the base plate 72. Thus, thermal expansion of the base plate 72 may be absorbed by the buffer 75 and does not have direct effect on the body 10. Therefore, the body 10 may be sufficiently prevented from being damaged due to the thermal expansion of the base plate 72.

The protection block 80 enclosing the tube 30 of the body 10 may be mounted on the base 70 and may face the bottom surface of the plate 20 of the body 10. Thus, the base 70 comprising a metal may be covered with the protection block 80 and protected from processing gases in the process chamber 200.

In an example embodiment, first, second and third sealing units 90, 95 and 96 may be installed to the stage 100, and thus the vacuum state of the process chamber 200 may not deteriorate even though the wirings 32 are extended from the electrode member 22 to the exterior of the process chamber 200.

The first sealing unit 90 may be interposed between the end portion of the tube 30 and the buffer 75 and the second sealing unit 95 may be interposed between the base plate 72 and the buffer 75. The third sealing unit 96 may be interposed between the base plate 72 and the bottom surface of the process chamber 200.

The substrate W on the stage 100 may include a silicon substrate such as a wafer for a semiconductor device and a glass substrate for a plant panel display device such as a liquid crystal display (LCD) device. Particularly, the glass substrate may include a TFT substrate on which a plurality of TFTs is formed and a color filter substrate on which a color filter is formed.

According to the example embodiments of the present invention, electrical short circuits of wirings in a tube may be prevented and the tube of a body of a stage may be prevented from being damaged even a base plate of a base is thermally expanded.

The foregoing is illustrative of example embodiments and is not to be construed as limiting thereof. Although a few example embodiments have been described, those skilled in the art will readily appreciate that many modifications are possible in the example embodiments without materially departing from the novel teachings and advantages of the present invention. Accordingly, all such modifications are intended to be included within the scope of the present invention as defined in the claims. In the claims, means-plus-function clauses are intended to cover the structures described herein as performing the recited function and not only structural equivalents but also equivalent structures. Therefore, it is to be understood that the foregoing is illustrative of various example embodiments and is not to be construed as limited to the specific example embodiments disclosed, and that modifications to the disclosed example embodiments, as well as other example embodiments, are intended to be included within the scope of the appended claims.

What is claimed is:

1. A stage for supporting a substrate, comprising:
a body on which the substrate is positioned, the body including a plate having an electrode member therein and a tube protruded from a bottom surface of the plate and through which wirings are extended from the electrode member; and
a first insulation section inserted into the tube and having a plurality of first holes through which the wirings are inserted, respectively.

2. The stage of claim 1, further comprising a filling member interposed between an inner wall of the tube and the first insulation section, so that a gap distance between the tube and the first insulation section is uniform along the inner wall of the tube.

3. The stage of claim 2, wherein the filling member includes a protrusion making contact with the first insulation section.

4. The stage of claim 1, wherein the electrode member in the plate includes a heating electrode for generating heat and the base includes a base plate on which the body is mounted and a buffer interposed between the base plate and the tube of the body, the buffer having a thermal expansion ratio higher than that of the tube of the body and lower than that of the base plate.

5. The stage of claim 4, wherein the first insulation section penetrates though the buffer and the base plate of the base, so that the first insulation section is extended to the exterior of the stage.

6. The stage of claim 4, wherein the buffer includes a first through-hole connected to the tube and the base plate includes a second through-hole connected to the first through-hole and the tube, and further comprises a second insulation section combined to the first insulation section through the first and second through-holes, the second insulation section including a plurality of second holes through which the wirings are individually inserted.

7. The stage of claim 4, further comprising a protection block interposed between the plate and the base plate and enclosing the tube of the body, so that the base plate is covered with the protection block and is protected from processing gases for processing the substrate.

8. The stage of claim 7, wherein the protection block is spaced apart from the plate having the heating electrode, to thereby prevent heat transfer from the plate to the protection block.

9. The stage of claim 8, wherein a gap distance between the protection block and the plate is in a range of about 0.05 mm to about 7 mm.

10. The stage of claim 7, wherein the protection block is separated into at least two portions.

11. The stage of claim 4, further comprising a first sealing unit interposed between the tube and the buffer and a second sealing unit interposed between the base plate and the buffer, so that the interior of the tube is sealed off from the exterior of the tube by the first and second sealing units.

12. The stage of claim 4, further comprising a first joint member for combining the tube and the buffer and a second joint member for combining the buffer and the base plate.

13. A stage for supporting a substrate, comprising:
a body on which the substrate is positioned, the body including a plate having a heating electrode for generating heat therein and a tube protruded from a bottom surface of the plate;
a base plate on which the body is mounted; and
a buffer interposed between the base plate and the tube and having a thermal expansion ratio higher than that of the tube of the body and lower than that of the base plate.

14. The stage of claim 13, further comprising a protection block interposed between the plate and the base plate and enclosing the tube of the body, so that the base plate is covered with the protection block and is protected from processing gases for processing the substrate.

15. An apparatus for processing a substrate, comprising:
a process chamber having a space in which the substrate is processed;
a gas supplier connected to the process chamber and through which process gases for processing the substrate is supplied into the process chamber; and
a stage positioned in the process chamber and supporting the substrate,
wherein the stage includes:
a body on which the substrate is positioned, the body including a plate having an electrode member therein and a tube protruded from a bottom surface of the plate and through which wirings are extended from the electrode member; and
a first insulation section inserted into the tube and having a plurality of first holes through which the wirings are inserted, respectively.

16. The apparatus of claim 15, wherein the electrode member in the plate includes a heating electrode for generating heat and the base includes a base plate on which the body is mounted and a buffer interposed between the base plate and the tube of the body, the buffer having a thermal expansion ratio higher than that of the tube of the body and lower than that of the base plate.

17. The apparatus of claim 16, wherein the stage further includes a protection block interposed between the plate and the base plate and enclosing the tube of the body, so that the base plate is covered with the protection block and is protected from processing gases for processing the substrate.
